(19) United States
(12) Patent Application Publication
(10) Pub. No.: US 2006/0015280 A1
(43) Pub. Date: Jan. 19, 2006

(54) Apparatus and method for determining angular position of a rotating disk

(75) Inventors: Johannis F. Blacquiere, Eindhoven (NL); Thomas J. De Hoog, Eindhoven (NL); Anthonius P. Janssen, Eindhoven (NL); Cornelis M. Schep, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/533,737

(22) PCT Filed: Oct. 16, 2003
(86) PCT No.: PCT/IB03/04640

§ 371 Date: May 4, 2005

(30) Foreign Application Priority Data
Nov. 6, 2002 (EP) 02292770.1

(51) Int. Cl. G01R 35/00

(52) U.S. Cl. 702/107

(57) ABSTRACT

This apparatus relates to a data carrier which rotates about an axis and on which a track is provided for containing said data, said track spiraling around a center, which apparatus comprises an angle measurer for many purposes. For obtaining this angular position information, for example an eccentricity measurer is used. The eccentricity is defined by the non-coincidence of the center and the axis. Application: The invention is well suited to small-size optical discs, CD systems, DVD systems, and Blu-Ray systems.

The present invention relates to an apparatus for processing data on a data carrier which rotates about an axis and on which a spirally shaped track is provided for containing said data, said track spiraling around a center, this apparatus comprising an angle measuring device.

This apparatus finds many applications, notably for data carriers constituted by optical discs. These optical discs can be read or written by the user. A problem often occurring is finding angular position information concerning, for example, the position of a certain data block (LBA) on an optical disc. This angle may be used, for example, to write visible/readable effects on an unused part of a disc, be it on the inside, the outside, or somewhere in the middle. Another application is to use the angular position for managing the defects on an optical disc. Thanks to this angular position information, it is possible to replace a defective block with another one in a spare area located in another angular position on the disc. Furthermore, this invention can be used as input for the servo system memory loop or any other function that needs angular or position information.

The angle information for high-speed drives is provided by a tachometer coupled to the turntable motor, which is an excellent and quite accurate angle measurer. In low speed (AV) drives, however, such a tachometer is not present, because it is technically possible to work without them. In order to keep the price of such drives as low as possible, a simple DC spindle motor is used without a tachometer. However, determining the relative angle of the disc is often needed. For example, this angular position information is needed in the servo system to implement the feed forward function (also known as the memory loop function).

The invention proposes a solution for providing this angle-determining method which can be implemented very easily without extra cost.

Such an apparatus is for this purpose characterized in that the angle measuring device is constituted by an eccentricity measurer sensitive to the non-coincidence of said axis and center.

The invention proposes a method of determining an angle of rotation of a disc.

A method of measuring the angle of a data carrier which rotates about an axis and on which a track is provided for containing said data, said track spiraling around a center, which method utilizes a servo mechanism for focusing and positioning a laser beam on the track, the method comprising the steps of:
analyzing the error signal of said servo mechanism,
detecting the eccentricity of the data carrier from this analysis,
deriving angular position information from the eccentricity defined by the non coincidence between the axis and the center.

These and other aspects of the invention are apparent from and will be elucidated, by way of a non-limitative example, with reference to the embodiments described hereinafter.

In the drawings:

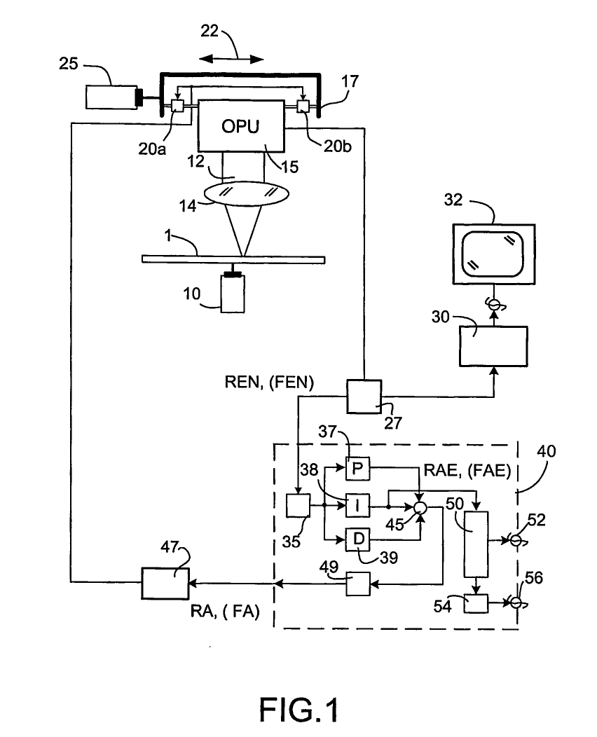

FIG. 1 shows an apparatus in accordance with the invention,

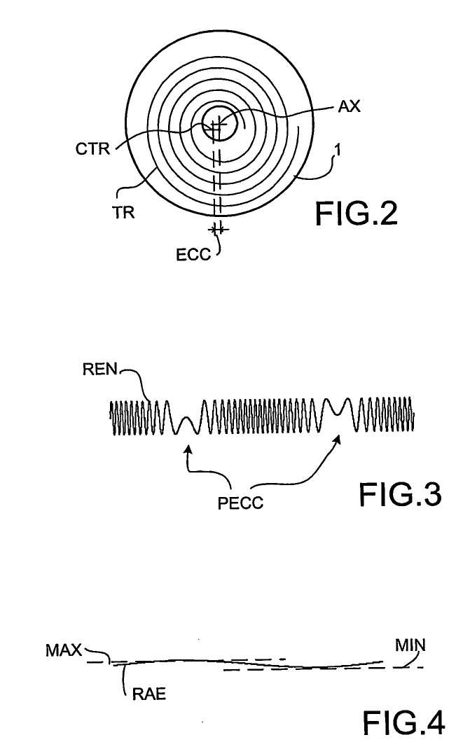

FIG. 2 shows an optical disc having eccentricity,

FIG. 3 is a time diagram showing a servo tracking signal disturbed by eccentricity,

FIG. 4 is a time diagram showing a signal derived from eccentricity useful for the invention.

FIG. 1 shows an apparatus in which a data carrier 1, notably an optical disc, is inserted. The data carrier is shown in cross-section. A lens 14 focuses a laser light beam 12 on this carrier, which is driven into a circular rotation by a motor 10. The laser is mounted in an Optical Pickup Unit (OPU) 15, which is placed in a sledge 17. Inside this sledge, some tracking devices 20a and 20b are provided for tracking the laser beam on the track. This unit 15 can be moved in directions indicated by arrows 22. For large movements, a motor 25 is used to move the entire sledge, and for small movements the tracking devices 20a and 20b inside the sledge are used. The signals at the output of the unit 15 are applied to a signal distributor 27. The distributor generates amongst other signals the signals REN (Radial Error Normalized) and FEN (Focus Error Normalized) for the servo tracking system and servo focusing system of the laser beam, respectively. A processing circuit 40 processes this signal by performing notably PID operations (and amplification). A preamp 35 sends a signal to the P, I, and D units, 37, 38, and 39. These units perform a direct operation, an integrator operation, and a differentiator operation, respectively. An adder 45, which adds up all signals provided by units 37, 38 and 39, generates a signal RA for a driving circuit 47 via a buffer amplifier 49. This signal RA acts on tracking devices 20a and 20b for positioning the laser beam on the track. Thus, a tracking servo mechanism is constituted.

FIG. 2 shows an optical disc on which a track TR is provided. This track spirals around a center CTR. The optical disc 1 rotates about an axis AX. This center CTR and the axis AX never coincide in practice. The distance between them is the eccentricity ECC. This eccentricity occurs in practice on every disc and the amount thereof varies for each of them. This amount is typically constant for a given disc. A servo mechanism constituted notably by the circuit 40 acts on tracking devices 20a and 20b (FIG. 1) to keep the focused beam on the track. The signal shown in FIG. 3 is obtained at the input of the circuit 40 (FIG. 1). It should be noted that the eccentricity generates this signal denoted PECC in this Figure, which means that RA is not provided to the tracking actuators 20a and 20b (FIG. 1). This signal REN is shown when the loop of the servomechanism is still open. The PECC signal as shown in FIG. 3 is the tracking signal related to half a disc rotation.

The invention utilizes the circuit 40, which is provided for tracking the laser beam to derive a signal. This circuit uses a filter known as a PID filter. The output of the unit 38, which unit performs an integration function, provides a signal RAE as shown in FIG. 4. When the loop is closed, this signal REN will become close to zero. In this case, the RAE signal is mainly used to compensate the eccentricity. When we look at the PID controller, the I-part will hold the eccentricity information in the closed loop situation as shown in this FIG. 4. This signal is processed by a peak/bottom detector 50 (see FIG. 1), which detects the maximum value MAX and the minimum value MIN. The peak/bottom detector 50 generates a ‘one pulse per revolution’ signal at its output. This output is applied to a frequency multiplier formed by a PLL device 54, which produces many pulses at the output 56. Counting them directly produces angular position information. So, it is possible to compensate for a missing motor tachometer.

The invention finds applications for optical discs. An accuracy of approximately 1° can be obtained for an optical disc.

In the above text, the processing of the signal REN has been notably disclosed. The invention also covers the case where the signal to be processed is the focusing signal FEN (Focus Error Normalized. See FIG. 1). This signal is used for focusing the laser beam onto the track with a similar device to that shown for the radial servo tracking. This signal is generated due to changing distances between the laser 15 and the medium 1 (FIG. 1). These changes are due to fact that said medium is not perfectly flat. The focusing device also uses a PID operator. The output of the I unit 38 is the FAE (Focus Actuator Error) signal. This signal is the input for an adaptive detector 50, which generates a ‘pulse per rotation’ signal that is the input for the PLL device 54 (FIG. 1). The I operation performed by the unit 38 provides a measure of the eccentricity.

Generating angular position information via the radial eccentricity signal (RAE) is the preferred embodiment of the invention. Using the focusing signal is an alternative for applying the invention.

1- An apparatus for processing data on a data carrier which rotates about an axis and on which tracks are provided for containing said data, said track spiraling around a center, said apparatus comprising an angle measuring device from which said angle information is derived, the angle measuring device being constituted by an eccentricity measurer sensitive to the non-coincidence of said axis and center.

2- An apparatus as claimed in claim 1, wherein a PID operator is provided for the tracking of a beam on the track, said operator comprising notably an I operator, characterized in that said eccentricity measurer takes account of the signal at the output of the I operator.

3- An apparatus as claimed in claim 2, comprising a peak/bottom detector at the output of the I operator.

4- An apparatus as claimed in claim 2, comprising a frequency multiplier for providing pulses, which multiplier is linked to the output of an I operator and from which multiplier angular position information is derived.

5- An apparatus as claimed in claim 1, characterized in that the PID operator acts on a radial tracking signal.

6- An apparatus as claimed in claim 1, characterized in that the PID operator acts on the focusing signal.

7- A method of measuring an indication of the angle of a data carrier which rotates about an axis and on which a track is provided for containing said data, said track spiraling around a center, which method utilizes a servo mechanism for positioning a beam on the track, the method comprising the steps of:
analyzing the error signal of said servomechanism,
detecting the eccentricity of the data carrier from this analysis,
deriving angular position information from the eccentricity defined by the non coincidence between the axis and the center.

8- A method of measuring as claimed in claim 7, comprising the steps of:
using a filter comprising notably an I operator,
processing the output signal of said I operator for providing said indication of the angular position information.

9- A method of measuring an indication of the angle of a data carrier which rotates about an axis and on which a track is provided for containing said data, said track spiraling around a center, which method utilizes a servo mechanism for focusing a beam on the track, the method comprising the steps of
analyzing the error signal of said servomechanism,
detecting the repetitive disturbances of the focus signal,
deriving angular position information from these disturbances.
